(19) United States
(12) Patent Application Publication
(10) Pub. No.: US 2025/0160173 A1
(43) Pub. Date: May 15, 2025

(54) DISPLAY DEVICE AND METHOD FOR FABRICATING THE SAME

(71) Applicant: Samsung Display Co., LTD., Yongin-si (KR)

(72) Inventors: Sang Duk LEE, Yongin-si (KR); Hoi Kwan LEE, Yongin-si (KR)

(73) Assignee: Samsung Display Co., LTD., Yongin-si (KR)

(21) Appl. No.: 18/736,911

(22) Filed: Jun. 7, 2024

(30) Foreign Application Priority Data
Nov. 9, 2023 (KR) 10-2023-0154043

(51) Int. Cl. H10K 59/80; H10K 59/12; H10K 59/131

(52) U.S. Cl. CPC H10K 59/873; H10K 59/1201; H10K 59/131; H10K 59/8791

(57) ABSTRACT

A display device includes: a substrate; a first electrode on the substrate; a pixel defining layer on the first electrode; a light emitting layer on the first electrode and the pixel defining layer, a second electrode on the light emitting layer; an encapsulation layer on the second electrode; an adhesive layer on the encapsulation layer, a reinforcement layer on the adhesive layer, and a functional layer on the reinforcement layer.

### CROSS-REFERENCE TO RELATED APPLICATION(S)

This application claims priority to and benefits of Korean Patent Application No. 10-2023-0154043 under 35 U.S.C. § 119, filed on Nov. 9, 2023, in the Korean Intellectual Property Office, the entire contents of which are incorporated herein by reference.

### BACKGROUND

### 1. Technical Field

Embodiments relate to a display device, specifically a display device capable of improving adhesion between a reinforcement layer and a functional layer, and a method of fabricating the display device.

### 2. Description of the Related Art

Various electronic devices that provide multimedia, such as televisions, mobile phones, navigation systems, computer monitors, and game consoles, are being developed. Electronic devices include a display panel that displays images. Various portable electronic devices such as mobile phones and tablets have been developed recently. Display devices that work together with portable electronic devices are being developed.

### SUMMARY

Embodiments provide a display device capable of improving adhesion between a reinforcement layer and a functional layer, and a method of fabricating the display device.

However, embodiments are not limited to those set forth herein. The above and other embodiments will become more apparent to one of ordinary skill in the art to which the disclosure pertains by referencing the detailed description of the disclosure given below.

According to an embodiment, a display device may include: a substrate; a first electrode on the substrate; a pixel defining layer on the first electrode; a light emitting layer on the first electrode and the pixel defining layer; a second electrode on the light emitting layer; an encapsulation layer on the second electrode; an adhesive layer on the encapsulation layer; a reinforcement layer on the adhesive layer; and a functional layer on the reinforcement layer.

In an embodiment, an interface between the reinforcement layer and the functional layer may be substantially flat.

In an embodiment, in plan view, the adhesive layer, the reinforcement layer, and the functional layer may have a same size as each other.

In an embodiment, a side surface of the adhesive layer, a side surface of the reinforcement layer, and a side surface of the functional layer may overlap each other.

In an embodiment, the side surface of the adhesive layer, the side surface of the reinforcement layer, and the side surface of the functional layer are aligned on the same line.

In an embodiment, a side surface of the reinforcement layer may include a carbonized area.

In an embodiment, the reinforcement layer may be formed of a material including at least one of an optically transparent resin, epoxy, or urethane.

In an embodiment, the functional layer may include a polarizer plate.

In an embodiment, the adhesive layer may include a pressure sensitive adhesive.

In an embodiment, the display device may further include an intermediate board connected to a pad area of the substrate.

In an embodiment, the display device may further include a circuit board connected to the intermediate board.

In an embodiment, the display device may further include a protective layer disposed on a lower portion of the substrate.

In an embodiment, the display device may further include a display driver disposed in a pad area of the substrate.

According to an embodiment, a method of fabricating a display device may include: forming a base module layer including placing a base reinforcement layer on a base functional layer; and placing a base adhesive layer on the base reinforcement layer; forming a module layer comprising a functional layer, a reinforcement layer, and an adhesive layer by cutting the base module layer comprising the base functional layer, the base reinforcement layer, and the base adhesive layer along a scribing line; and placing the module layer on an encapsulation layer of a substrate.

In an embodiment, the forming of the module layer may include cutting the base module layer by irradiating a laser beam to the base module layer along the scribing line.

In an embodiment, the cutting of the module layer may include cutting the base adhesive layer, the base reinforcement layer, and the base functional layer by irradiating the laser beam to the base adhesive layer, the base reinforcement layer, and the base functional layer along the scribing line.

In an embodiment, the placing of the module layer on the encapsulation layer of the substrate may include attaching an adhesive layer of the module layer to the encapsulation layer.

In an embodiment, the reinforcement layer is formed of a material including at least one of an optically transparent resin, epoxy, or urethane.

In an embodiment, the functional layer may include a polarizer plate.

In an embodiment, the adhesive layer may include a pressure sensitive adhesive.

In an embodiment, the placing of the base reinforcement layer on the base functional layer may include continuously applying a raw material of the base reinforcement layer from an edge portion of the base functional layer to another edge portion of the base functional layer.

According to a display device and a manufacturing method of an embodiment, since a bump shape and a slope shape of a reinforcement layer are formed in a portion discarded from a base module layer after a cutting process, the bump shape and slope shape are not formed in the module layer separated from the base module layer after the cutting process. Accordingly, the reinforcement layer of the module layer may have a flat surface. Therefore, the adhesion between the functional layer and the reinforcement layer may be improved.

According to a method of fabricating a display device of an embodiment, since a plurality of module layers may be manufactured from the base module layer, a display device may be manufactured in a faster time compared to the process of independently forming an adhesive layer, a reinforcement layer, and a functional layer for each encapsulation layer.

The effects of the disclosure are not limited to the above-described effects and other effects which are not described herein will become apparent to those skilled in the art from the following description.

### BRIEF DESCRIPTION OF THE DRAWINGS

The above and other aspects and features of the disclosure will become more apparent by describing in detail embodiments thereof with reference to the attached drawings, in which:

FIG. 1 is a schematic cross-sectional view of a display device according to an embodiment;

FIG. 2 is a schematic plan view of a base functional layer;

FIG. 3 is a schematic plan view of a base reinforcement layer disposed on the base functional layer of FIG. 2;

FIG. 4 is a schematic plan view of a base adhesive layer disposed on the base reinforcement layer of FIG. 3;

FIG. 5 is a schematic cross-sectional view taken along line I-I′ of FIG. 4;

FIG. 6 is a schematic diagram for explaining a cutting process in respect to the base module layer of FIG. 5;

FIG. 7 is a schematic plan view of any one of module layers separated from the base module layer of FIG. 6;

FIG. 8 is a schematic cross-sectional view taken along line II-II′ of FIG. 7;

FIG. 9 is a schematic cross-sectional view for describing a process of a method of adhering the module layer of FIG. 8 to an encapsulation layer of a substrate;

FIG. 10 is a schematic cross-sectional view illustrating a state in which the module layer and the encapsulation layer of FIG. 9 are adhered;

FIG. 11 is a schematic cross-sectional view taken along line III-III′ of FIG. 3; and

FIG. 12 is a schematic cross-sectional view taken along line IV-IV′ of FIG. 3.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described in detail with reference to the accompanying drawings.

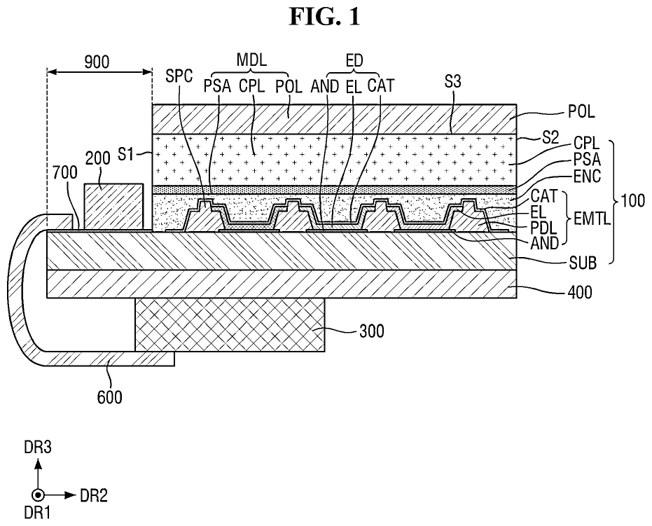

FIG. 1 is a schematic cross-sectional view of a display device according to an embodiment.

As illustrated in FIG. 1, a display device according to an embodiment may include a display panel 100, a display driver 200, an intermediate board 600, a circuit board 300, and a functional layer POL.

The display panel 100 may include a substrate SUB, a light emitting element layer EMTL, an encapsulation layer ENC, an adhesive layer PSA, and a reinforcement layer CPL arranged along a third direction DR3. For example, the display panel 100 may further include a transistor layer disposed between the substrate SUB and the light emitting element layer EMTL, a touch sensing unit disposed on the encapsulation layer ENC, and a color filter layer on the touch sensing unit. For example, the touch sensing unit and the color filter layer may be disposed between the encapsulation layer ENC and the adhesive layer PSA. For example, the touch sensing unit may be disposed between the encapsulation layer ENC and the color filter layer, and the color filter layer may be disposed between the touch sensing unit and the adhesive layer PSA.

A protective layer 400 may be disposed on the lower portion of the display panel 100. For example, the protective layer 400 may be disposed below the substrate SUB. For example, the protective layer 400 may be disposed on the opposite side of the functional layer POL. The display panel 100 may be disposed between the protective layer 400 and the functional layer POL. The protective layer 400 may prevent external light from entering the display panel 100. For example, the protective layer 400 may prevent external shock from being transmitted to the lower portion of the display panel 100. The protective layer 400 may have a film form.

The substrate SUB may be disposed on the protective layer 400. The substrate SUB may be a flexible substrate that is bendable, foldable, rollable, etc. For example, the substrate SUB may include polymer resin such as polyimide (PI). However, embodiments are not limited thereto. For another example, the substrate SUB may include a glass material or a metal material.

The transistor layer may be disposed on the substrate SUB. The transistor layer may include thin film transistors of a pixel circuit of the pixels. The transistor layer may further include gate lines, data lines, power lines, gate control lines, fan-out lines connecting a display driver and the data lines, and lead lines connecting the display driver and a pad unit. Each of the transistors may include a semiconductor area, a source electrode, a drain electrode, and a gate electrode. For example, in case that a gate driver is formed on a side of a non-display area of the display panel 100, the gate driver may include the thin film transistors.

The transistor layer may be disposed in a display area and a non-display area of the substrate SUB. Thin film transistors, gate lines, data lines, and power lines of each pixel of the thin film transistor layer may be disposed in the display area. Gate control lines and fan-out lines of the transistor layer may be disposed in the non-display area.

The light emitting element layer EMTL may be disposed on the thin film transistor layer. The light emitting element layer EMTL may include light emitting elements ED that emit light by sequentially stacking a first electrode AND, a light emitting layer EL, and a second electrode CAT and a pixel defining layer PDL defining the pixels. The light emitting elements ED of the light emitting element layer EMTL may be disposed in the display area of the substrate SUB. According to an embodiment, the pixel defining layer PDL may further include a spacer SPC protruding from the top (or upper surface) of the pixel defining layer PDL in the third direction DR3. The pixel defining layer PDL and the spacer SPC may be integral with each other. The spacer SPC may support a mask (e.g., fine metal mask), which is used informing the light emitting layer EL.

For example, the light emitting layer EL may be an organic light emitting layer EL including an organic material. The light emitting layer EL may include a hole transporting layer, an organic light emitting layer, and an electron transporting layer. In case that the first electrode AND receives a certain voltage (e.g., data voltage) through the thin film transistor of the thin film transistor layer and the second electrode CAT receives a common voltage (e.g., cathode voltage), holes and electrons may be moved to the organic light emitting layer EL through the hole transporting layer and the electron transporting layer, respectively, and may be combined with each other in the organic light emitting layer EL to emit light. For example, the first electrode AND may be an anode electrode, and the second electrode CAT may be a cathode electrode, but embodiments are not limited thereto.

For another example, the light emitting elements ED may include a quantum dot light emitting diode including a quantum dot light emitting layer EL, an inorganic light emitting diode including an inorganic semiconductor, or a micro light emitting diode.

The encapsulation layer ENC may cover the top (or upper) and side surfaces of the light emitting element layer EMTL and protect the light emitting element layer EMTL. The encapsulation layer ENC may include at least one inorganic layer and at least one organic layer to encapsulate the light emitting element layer EMTL.

A touch sensing unit may be disposed on the encapsulation layer ENC. The touch sensing unit may include touch electrodes for detecting a user's touch in a capacitive manner, and touch lines connecting the touch electrodes and a touch driver. For example, the touch sensing unit may sense the user's touch using a mutual capacitance method or a self-capacitance method.

The adhesive layer PSA may be disposed on the encapsulation layer ENC. For example, the adhesive layer PSA may be disposed on the touch sensing unit to overlap the encapsulation layer ENC in the third direction DR3. The adhesive layer PSA may include, for example, a pressure sensitive adhesive such as an optically clear adhesive.

The reinforcement layer CPL may be disposed on the adhesive layer PSA. For example, the reinforcement layer CPL may be disposed between the adhesive layer PSA and the functional layer POL. The reinforcement layer CPL may be in contact with the adhesive layer PSA and the functional layer POL. The reinforcement layer CPL may, for example, protect the display panel 100 from an external shock. The reinforcement layer CPL may be, for example, formed of a material including an optically transparent resin having a high intensity and a flexible characteristics. In an embodiment, the reinforcement layer CPL may be formed of a material including at least one of epoxy or urethane.

According to an embodiment, the interface between the reinforcement layer CPL and the functional layer POL may be substantially flat. For example, an upper surface S3 of the reinforcement layer CPL may be substantially flat.

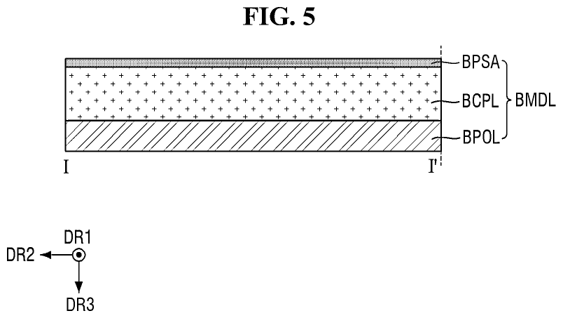

According to an embodiment, the adhesive layer PSA, the reinforcement layer CPL, and the functional layer POL may form a module layer MDL. For example, the module layer MDL may be disposed on the encapsulation layer ENC of the display panel 100, and the module layer MDL may include the adhesive layer PSA, the reinforcement layer CPL, and the functional layer POL, sequentially stacked along the third direction DR3. For example, the adhesive layer PSA, the reinforcement layer CPL, and the functional layer POL of the module layer MDL may be respectively manufactured by being cut from a base module layer BMDL (of FIG. 5) including a base adhesive layer BPSA, a base reinforcement layer BCPL, and a base functional layer BPOL in cell units.

In plan view, the adhesive layer PSA, the reinforcement layer CPL, and the functional layer POL may have the same size. For example, when the functional layer POL is viewed from the opposite direction of the third direction DR3 (hereinafter, a third reverse direction), the area of the adhesive layer PSA, the area of the reinforcement layer CPL, and the area of the functional layer POL may be the same as each other. For example, the area of each corresponding layer (e.g., PSA, CPL, or POL) may be a value obtained by multiplying the magnitude in the first direction DR1 and the magnitude in the second direction DR2 of the corresponding layer (e.g., PSA, CPL, or POL)

A side of the adhesive layer PSA, a side of the reinforcement layer CPL, and a side of the functional layer POL may overlap with each other. For example, the edge portion (or end portion) of the adhesive layer PSA, the edge portion (or end portion) of the reinforcement layer CPL, and the edge portion (or end portion) of the functional layer POL may overlap with each other.

The side of the adhesive layer PSA, the side of the reinforcement layer CPL, and the side of the functional layer POL may be disposed on the same line. For example, the edge portion (or end portion) of the adhesive layer PSA, the edge portion (or end portion) of the reinforcement layer CPL, and the edge portion (or end portion) of the functional layer POL may be arranged along an imaginary straight line. Accordingly, the edge portion (or end portion) of the adhesive layer PSA, the edge portion (or end portion) of the reinforcement layer CPL, and the edge portion (or end portion) of the functional layer POL may be arranged to coincide in the third direction DR3.

At least a portion of the module layer MDL may include a carbonized area. For example, at least one side of the adhesive layer PSA, the reinforcement layer CPL, and the functional layer POL of the module layer MDL may include a carbonized area. In an embodiment, at least one of a first side S1 of the module layer MDL (for example, at least one of the first side of the adhesive layer PSA, the first side of the reinforcement layer CPL, and the first side of the functional layer POL) and a second side S2 of the module layer MDL (for example, at least one of the second side of the adhesive layer PSA, the second side of the reinforcement layer CPL, and the second side of the functional layer POL) may include a carbonized area. The carbonized area may be a blackened area. The first side S1 of the module layer MDL may be disposed adjacent to the display driver 200, and the second side S2 of the module layer MDL may be disposed on the opposite side of the first side S1 in a second direction DR2.

According to an embodiment, at least one of the other sides adjacent to the first side S1 of the module layer MDL in a first direction DR1 and/or the second direction DR2 and connected to the first side S1 may have the carbonized area described above. For example, in plan view, the module layer MDL may have a square shape including four sides (e.g., the first side S1, the second side S2, a third side, and a fourth side), and at least one of the third side and the fourth side may have a carbonized area. For example, the third side may be disposed between a portion of the first side S1 and a portion of the second side S2 and be connected to the portion of the first side S1 and the portion of the second side S2. For example, the fourth side may be disposed between another portion of the first side S1 and another portion of the second side S2 and be connected to the another portion of the first side S1 and the another portion of the second side S2. The fourth side of the module layer MDL may be positioned opposite to the third side in the first direction DR1.

The display driver 200 may output signals and voltages for driving the display panel 100. The display driver 200 may supply data voltages to data lines. The display driver 200 may supply a power voltage to a power line and a gate control signal to the gate driver. The display driver 200 may be formed of an integrated circuit (IC) and mounted on the display panel 100 using a chip on glass (COG) method, a chip on plastic (COP) method, or an ultrasonic bonding method. For example, the display driver 200 may be disposed in the non-display area of the substrate SUB. As an example, the display driver may be disposed in a pad area 900 (or a mounting area) of the non-display area.

The intermediate board 600 may physically and electrically connect the substrate SUB and the circuit board 300 of the display panel 100 to each other. For example, a side of the intermediate board 600 may be physically and electrically connected to the pad area 900 of the display panel 100, and another side of the intermediate board 600 may be physically and electrically connected to the circuit board 300. The intermediate board 600 may be bent in U-shape.

The side of the intermediate board 600 may be connected to the substrate SUB through a first conductive adhesive member. For example, the side of the intermediate board 600 may be connected to a pad electrode 700 disposed in the pad area 900 of the substrate SUB through a first conductive adhesive member. The pad electrode 700 of the substrate SUB may also be connected to the display driver 200 described above. Accordingly, the intermediate board 600 and the display driver 200 may be electrically connected to each other. For example, the first conductive adhesive member may be an anisotropic conductive film (ACF).

In an embodiment, the intermediate board 600 may be a flexible film, such as a flexible printed circuit board, a printed circuit board, or a chip on film.

The other side of the intermediate board 600 may be connected to the circuit board 300 through a second conductive adhesive member. For example, the other side of the intermediate board 600 may be connected to the circuit board 300 through a second conductive adhesive member. Accordingly, the circuit board 300, the intermediate board 600, and the display driver 200 may be electrically connected to each other. For example, the second conductive adhesive member may be an anisotropic conductive film (ACF).

In an embodiment, the circuit board 300 may be a flexible film, such as a flexible printed circuit board, a printed circuit board, or a chip on film.

The circuit board 300 may be disposed below the protective layer 400. For example, circuit components such as a touch driver and a power supply unit may be disposed on the circuit board 300. For example, the touch driver and the power supply unit may be mounted on the circuit board 300. The circuit components (e.g., at least one of the touch driver and the power supply unit) of the circuit board 300 may be electrically connected to the display driver 200 and the display panel 100 on the substrate SUB through the circuit board 300 and the intermediate board 600.

The touch driver may be electrically connected to the touch sensing unit of the display panel 100. The touch driver may supply a touch driving signal to touch electrodes of the touch sensing unit and may sense an amount of change in capacitance between the touch electrodes. For example, the touch driving signal may be a pulse signal having a certain frequency. The touch driver may calculate whether an input is made and input coordinates based on an amount of change in capacitance between the touch electrodes. The touch driver may be formed of an integrated circuit (IC).

The power supply unit may supply a power voltage to the display driver 200 and the display panel 100. The power supply unit may generate a driving voltage, which is supplied to a driving voltage line, generate an initialization voltage, which is supplied to an initialization voltage line, and generate a common voltage, which is supplied to a second electrode CAT that is common to the light emitting elements ED of pixels. For example, the driving voltage may be a high potential voltage for driving the light emitting element ED, and the common voltage may be a low potential voltage for driving the light emitting element ED.

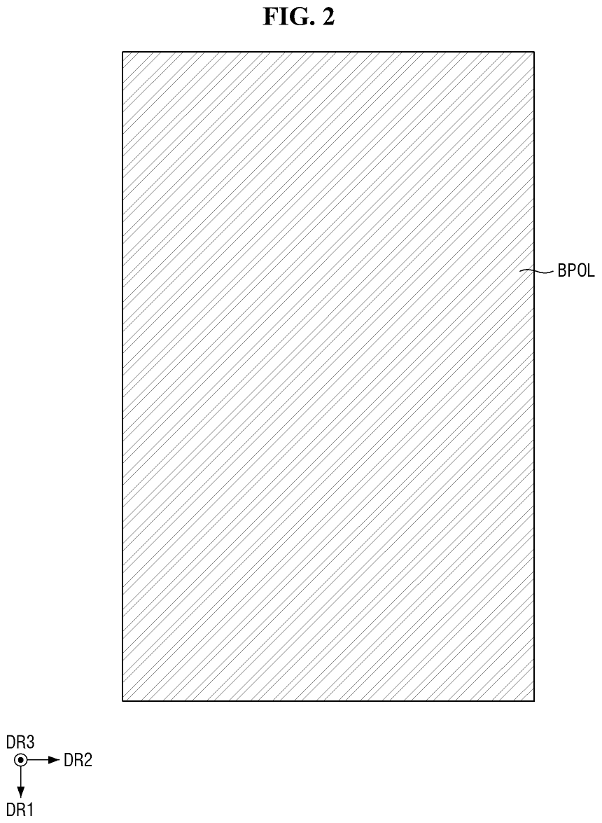

Hereinafter, a method of fabricating a display device according to an embodiment in reference to FIGS. 2 to 10 will be described as below.

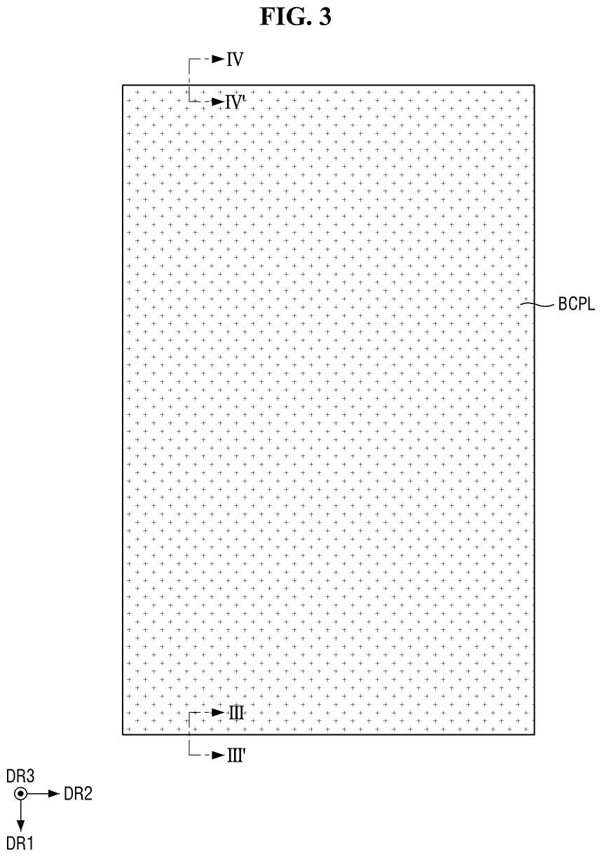

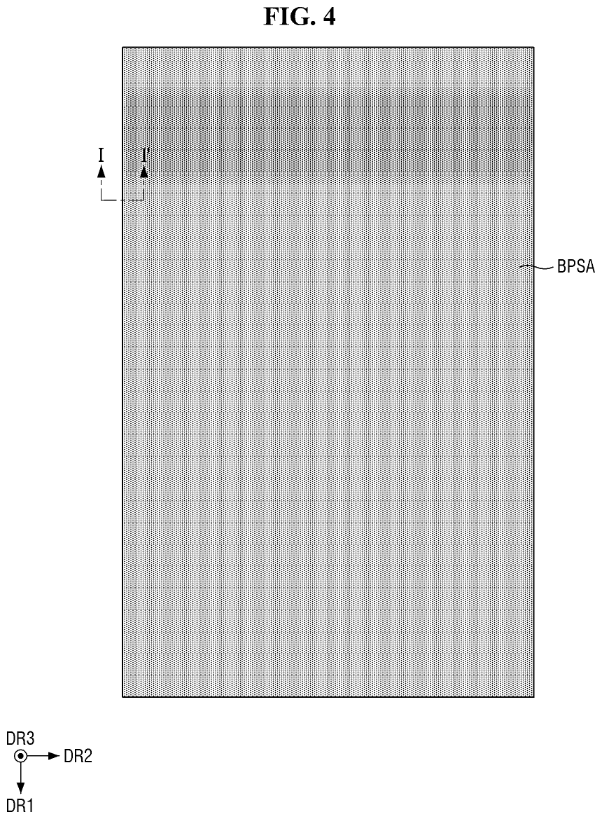

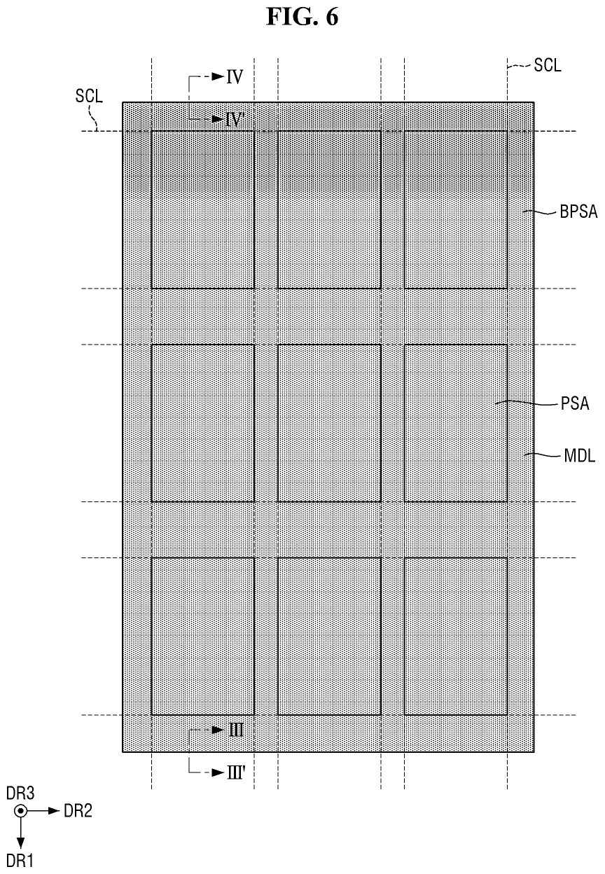

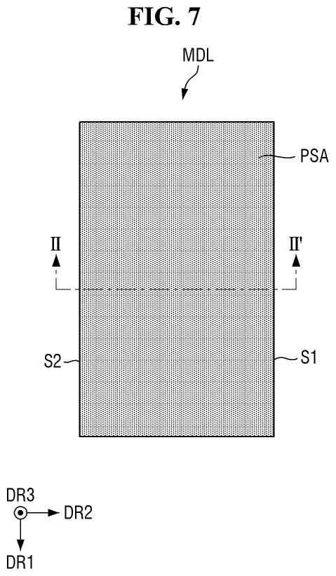

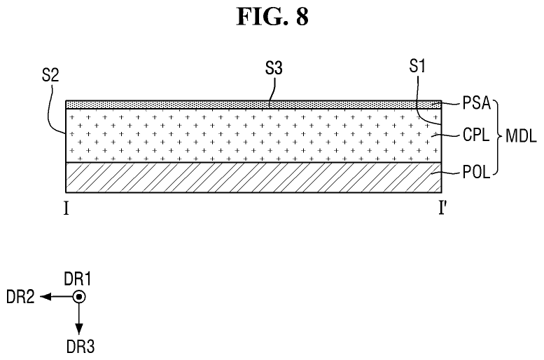

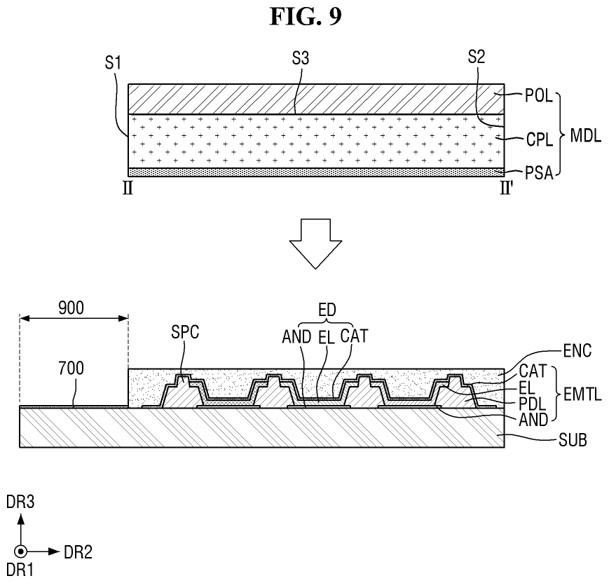

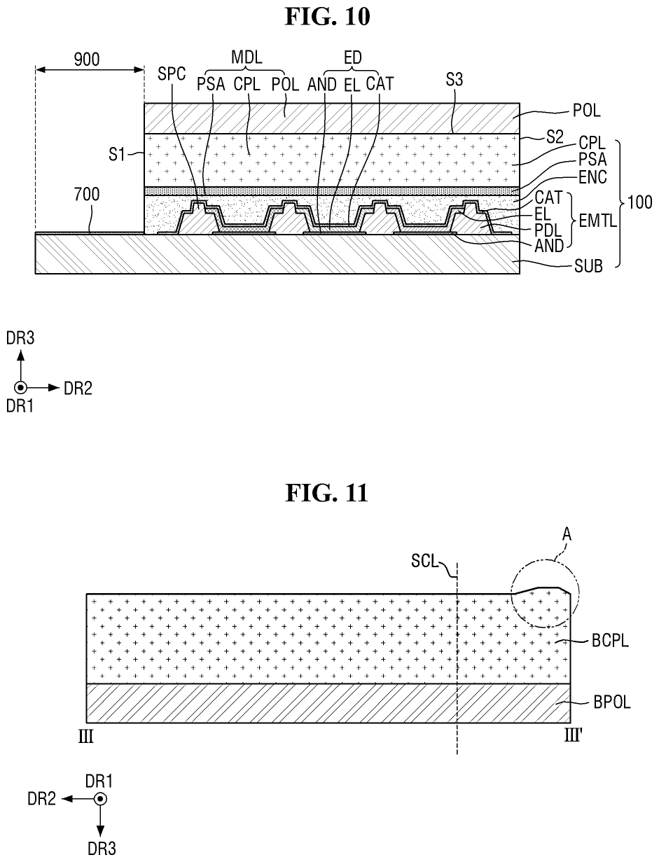

FIG. 2 is a schematic plan view of the base functional layer BPOL. FIG. 3 is a schematic plan view of the base reinforcement layer BCPL disposed on the base functional layer BPOL of FIG. 2. FIG. 4 is a schematic plan view of the base adhesive layer BPSA disposed on the base reinforcement layer BCPL of FIG. 3. FIG. 5 is a schematic cross-sectional view taken along line I-I′ of FIG. 4. FIG. 6 is a schematic diagram for explaining a cutting process in respect to the base module layer BMDL of FIG. 5. FIG. 7 is a schematic plan view of any one of module layers MDL separated from the base module layer BMDL of FIG. 6. FIG. 8 is a schematic cross-sectional view taken along line II-II′ of FIG. 7. FIG. 9 is a schematic cross-sectional view for describing a process of a method of adhering the module layer MDL of FIG. 8 to the encapsulation layer ENC of a substrate. FIG. 10 is a schematic cross-sectional view illustrating a state in which the module layer MDL and the encapsulation layer ENC of FIG. 9 are adhered.

As illustrated in FIG. 2, the base functional layer BPOL may be prepared. The base functional layer BPOL and the functional layer POL described above may be made of the same material as each other.

As illustrated in FIG. 3, the base reinforcement layer BCPL may be disposed on the base functional layer BPOL. For example, the base reinforcement layer BCPL may be disposed on the entire surface of the base functional layer BPOL. In an embodiment for this, first, a raw material of the base reinforcement layer BCPL (e.g., optically transparent resin, or a material including at least one of epoxy and urethane) may be applied on the base functional layer BPOL, and a curing process in respect to the raw material may be performed, thereby forming the base reinforcement layer BCPL. For example, the curing process may include, for example, at least one of an ultraviolet curing process of irradiating ultraviolet rays to the raw material of the base reinforcement layer BCPL and a thermal curing process of applying heat to the raw material. The base reinforcement layer BCPL and the reinforcement layer CPL described above may be made of the same material as each other.

As illustrated in FIG. 4, the base adhesive layer BPSA may be disposed on the base reinforcement layer BCPL. The base adhesive layer BPSA and the adhesive layer PSA described above may be made of the same material as each other.

As illustrated in FIG. 5, the base module layer BMDL including the base functional layer BPOL, the base reinforcement layer BCPL, and the base adhesive layer BPSA sequentially stacked along the third reverse direction based on the base functional layer BPOL may be fabricated.

Thereafter, as illustrated in FIG. 6, the base module layer BMDL may be cut along scribing lines SCL. Accordingly, the base functional layer BPOL, the base reinforcement layer BCPL, and the base adhesive layer BPSA of the base module layer BMDL may be cut along the scribing lines SCL described above.

The module layers MDL may be provided in cell units from the base module layer BMDL through a cutting process. As an example illustrated in FIG. 6, nine module layers MDL may be provided from a single base module layer BMDL. FIGS. 7 and 8 illustrate examples of a module layer MDL among nine module layers MDL separated from the base module layer BMDL. As illustrated in FIGS. 7 and 8, the module layer MDL may include the functional layer POL separated from the base functional layer BPOL, the reinforcement layer CPL separated from the base reinforcement layer BCPL, and the adhesive layer PSA separated from the base adhesive layer BPSA.

In an embodiment, the base module layer BMDL may be cut by a wheel or a laser beam during the cutting process. In case that the base module layer BMDL is cut by a laser beam, at least a portion of the cut surface of the module layer MDL that is cut along the scribing line SCL may be carbonized. For example, at least a portion of the cut surface of the module layer MDL may each have a carbonized area (or blackened area). For example, as illustrated in FIG. 8, the first side S1 of the module layer MDL (for example, at least one of the first side of the functional layer POL, the first side of the reinforcement layer CPL, and the first side of the adhesive layer PSA) and the second side S2 of the module layer MDL (for example, at least one of the second side of the functional layer POL, the second side of the reinforcement layer CPL, and the second side of the adhesive layer PSA) may have a carbonized area (or blackened area).

As illustrated in FIG. 9, the module layer MDL described above may be disposed on the substrate SUB including the encapsulation layer ENC. For example, the module layer MDL may be disposed on the encapsulation layer ENC. For example, the module layer MDL may be disposed on the encapsulation layer ENC so that the adhesive layer PSA of the module layer MDL may be in contact with the encapsulation layer ENC. As illustrated in FIG. 10, the module layer MDL and the encapsulation layer ENC may be adhered to each other.

As illustrated in FIG. 1, the display driver 200 may be disposed on the pad area 900 of the display panel 100.

As illustrated in FIG. 1, the protective layer 400 may be disposed on the lower surface of the display panel 100 (e.g., the lower surface of the substrate SUB).

As illustrated in FIG. 1, a side of the intermediate board 600 may be connected to the pad area 900 and the circuit board 300 may be connected to another side of the intermediate board 600.

As illustrated in FIG. 1, the intermediate board 600 may be bent so that the circuit board 300 and the protective layer 400 may face each other.

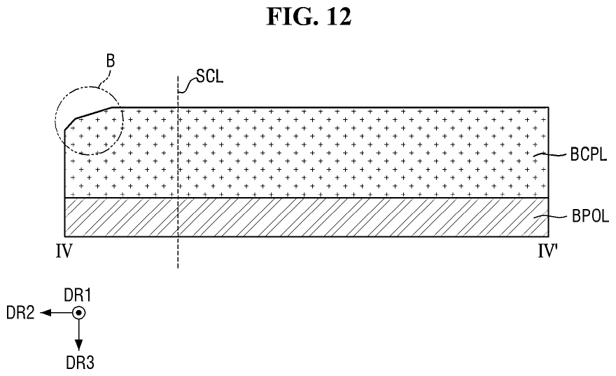

As the upper surface of the reinforcement layer CPL (for example, a side of the reinforcement layer CPL facing the functional layer POL) is flattened, the adhesion between the reinforcement layer CPL and the functional layer POL may be improved. Accordingly, since the adhesion between the reinforcement layer CPL and the functional layer POL is improved, the problem of the functional layer POL being separated from the reinforcement layer CPL may be solved or prevented. For example, the principle by which the reinforcement layer CPL of the display panel 100 (e.g., the upper surface S3 of the reinforcement layer CPL) according to an embodiment may be flattened will be described in detail with reference to FIGS. 11 and 12 as the followings.

FIG. 11 is a schematic cross-sectional view taken along line III-III′ of FIG. 3, and FIG. 12 is a cross-sectional view taken along line IV-IV′ of FIG. 3.

According to a method of fabricating a display device according to an embodiment, since a cutting process (e.g., the process illustrated in FIG. 6) is performed after the base reinforcement layer BCPL is formed on the base functional layer BPOL, a non-flat portion of the base reinforcement layer BCPL may be formed at the edge portion of the base reinforcement layer BCPL. More specific details will be given as the following.

The raw material of the base reinforcement layer BCPL may be applied on the base functional layer BPOL by a slit coating method. For example, a slit coating device may discharge raw materials through a nozzle with moving from an edge portion of the base functional layer BPOL to the other edge portion of the base functional layer BPOL positioned on the opposite side of the edge portion, thereby applying the raw materials continuously to the entire surface of the base functional layer BPOL. For example, due to the characteristics of the slit coating device, the raw materials discharged first and last from the nozzle of the slit coating device may protrude more in the third reverse direction or may be more depressed in the third direction DR3 than other parts from the edge portion of the base functional layer BPOL as shown in area A of FIG. 11 or area B of FIG. 12. For example, since the nozzle of the slit coating device is positioned at an edge portion of the base functional layer BPOL at the time of initial discharge of the slit coating device, and the nozzle of the slit coating device is positioned at the other edge portion of the base functional layer BPOL at the time of final discharge of the slit coating device, the edge portion of the base reinforcement layer BCPL may have a bump shape illustrated in area A of FIG. 11 or a slope shape illustrated in area B of FIG. 12.

However, since the bump shape and slope shape described above are formed in the portion discarded after the cutting process from the base module layer BMDL (or the base reinforcement layer BCPL), the bump shape and the slope shape may not be formed in the module layer MDL separated from the base module layer BMDL (or the base reinforcement layer BCPL). For example, the reinforcement layer CPL of the module layer MDL may have a flat surface. For example, the upper surface S3 of the reinforcement layer CPL of the module layer MDL may have a flat surface. Therefore, according to the display device of an embodiment, the adhesion between the functional layer POL and the reinforcement layer CPL may be improved. According to a method of fabricating a display device according g to an embodiment, since module layers MDL may be manufactured from the base module layer BMDL, the display device may be manufactured in a faster time compared to the process of independently forming an adhesive layer PSA, a reinforcement layer CPL, and a functional layer POL for each encapsulation layer ENC.

In case that the process of individually forming the reinforcement layer CPL for each encapsulation layer ENC is performed, due to the characteristics of the slit coating device described above, the reinforcement layer CPL portions of an edge portion and another edge portion of the adhesive layer PSA may become non-flat. Accordingly, in the case of such a manufacturing method, not only is it inefficient, but the adhesion between the reinforcement layer CPL and the functional layer POL is weakened, which may cause a problem of the functional layer POL separating from the reinforcement layer CPL.

According to an embodiment, the base reinforcement layer BCPL (or the reinforcement layer CPL) described above may be formed in the form of a film. For example, a base reinforcement film (or reinforcement film) may be used instead of the base reinforcement layer BCPL (or the reinforcement layer CPL). For example, the base module layer BMDL illustrated in FIGS. 4 and 5 may be provided in a pre-manufactured form. For example, the base module layer BMDL may be provided in a form in which the base functional layer BPOL, the base reinforcement layer BCPL, and the base adhesive layer are integrated. The base module layer BMDL may be separated into module layers MDL through the cutting process described above and then adhered to the encapsulation layer ENC.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate;
a first electrode on the substrate;
a pixel defining layer on the first electrode;
a light emitting layer on the first electrode and the pixel defining layer;
a second electrode on the light emitting layer;
an encapsulation layer on the second electrode;
an adhesive layer on the encapsulation layer;
a reinforcement layer on the adhesive layer; and
a functional layer on the reinforcement layer.

2. The display device of claim 1, wherein an interface between the reinforcement layer and the functional layer is substantially flat.

3. The display device of claim 1, wherein, in plan view, the adhesive layer, the reinforcement layer, and the functional layer have a same size as each other.

4. The display device of claim 3, wherein a side surface of the adhesive layer, a side surface of the reinforcement layer, and a side surface of the functional layer overlap each other.

5. The display device of claim 4, wherein the side surface of the adhesive layer, the side surface of the reinforcement layer, and the side surface of the functional layer are aligned on a same line.

6. The display device of claim 1, wherein a side surface of the reinforcement layer includes a carbonized area.

7. The display device of claim 1, wherein the reinforcement layer is formed of a material including at least one of an optically transparent resin, epoxy, or urethane.

8. The display device of claim 1, wherein the functional layer comprises a polarizer plate.

9. The display device of claim 1, wherein the adhesive layer comprises a pressure sensitive adhesive.

10. The display device of claim 1, further comprising:
an intermediate board connected to a pad area of the substrate.

11. The display device of claim 10, further comprising:
a circuit board connected to the intermediate board.

12. The display device of claim 1, further comprising:
a protective layer disposed on a lower portion of the substrate.

13. The display device of claim 1, further comprising:
a display driver disposed in a pad area of the substrate.

14. A method of fabricating a display device, the method comprising:
forming a base module layer, the forming of the base module layer comprising:
placing a base reinforcement layer on a base functional layer; and
placing a base adhesive layer on the base reinforcement layer;
forming a module layer comprising a functional layer, a reinforcement layer, and an adhesive layer by cutting the base module layer comprising the base functional layer, the base reinforcement layer, and the base adhesive layer along a scribing line; and
placing the module layer on an encapsulation layer of a substrate.

15. The method of claim 14, wherein the forming of the module layer comprises cutting the base module layer by irradiating a laser beam to the base module layer along the scribing line.

16. The method of claim 15, wherein the cutting of the module layer comprises cutting the base adhesive layer, the base reinforcement layer, and the base functional layer by irradiating the laser beam to the base adhesive layer, the base reinforcement layer, and the base functional layer along the scribing line.

17. The method of claim 14, wherein the placing of the module layer on the encapsulation layer of the substrate comprises attaching an adhesive layer of the module layer to the encapsulation layer.

18. The method of claim 14, wherein the reinforcement layer is formed of a material including at least one of an optically transparent resin, epoxy, or urethane.

19. The method of claim 14, wherein the functional layer comprises a polarizer plate.

20. The method of claim 14, wherein the adhesive layer comprises a pressure sensitive adhesive.

21. The method of claim 14, wherein the placing of the base reinforcement layer on the base functional layer comprises continuously applying a raw material of the base reinforcement layer from an edge portion of the base functional layer to another edge portion of the base functional layer.
